(19) United States
(12) Patent Application Publication
(10) Pub. No.: US 2010/0213490 A1
(43) Pub. Date: Aug. 26, 2010

(54) SEALING COMPOSITION FOR LIGHT EMITTING DEVICE AND LIGHT EMITTING DEVICE INCLUDING THE SAME

(76) Inventors: Il Woo PARK, Suwon (KR); Yong Chun Kim, Seongnam (KR); Na Na Park, Seoul (KR); Bang Won Oh, Seongnam (KR)

Correspondence Address: MCDERMOTT WILL & EMERY LLP, 600 13TH STREET, N.W., WASHINGTON, DC, 20005-3096, US

(21) Appl. No.: 12/711,636

(22) Filed: Feb. 24, 2010

(30) Foreign Application Priority Data
Feb. 24, 2009 (KR) 10-2009-0015220

(51) Int. Cl. H01L 33/50; H01L 33/56; H01L 33/58; C08L 63/04; C09K 11/02

(52) U.S. Cl. 257/98; 257/100; 525/403; 252/301.36; 257/E33.059; 257/E33.068; 257/E33.074

(57) ABSTRACT

According to an aspect of the present invention, there is provided a sealing composition for a light emitting device, the sealing composition including: a silicone/epoxy compound resin including a silicone resin having at least one silicon atom-bonded hydroxyl group and an epoxy resin having at least one oxirane group while the hydroxyl group of the silicone resin and the oxirane group of the epoxy resin are chemically bound to each other.

### CROSS-REFERENCE TO RELATED APPLICATIONS

This application claims the priority of Korean Patent Application No. 10-2009-0015220 filed on Feb. 24, 2009, in the Korean Intellectual Property Office, the disclosure of which is incorporated herein by reference.

### BACKGROUND OF THE INVENTION

1. Field of the Invention

The present invention relates to a sealing composition for a light emitting device, and more particularly, to a sealing composition for a light emitting device that has mechanical stability as well as resistance to heat and discoloration, and a light emitting device including the same.

2. Description of the Related Art

In general, a light emitting diode chip has a superior monochromatic peak wavelength and high degrees of luminous efficiency, and allows for miniaturization. Thus, this type of light emitting diode (LED) chip is being used widely as a light source in various displays.

Typically, a light emitting device package has a light emitting diode mounted therein and a transparent resin encapsulation unit protecting the light emitting diode. Particularly, in order for a resin encapsulation unit, which is employed in a white light emitting device, to function as a wavelength conversion unit, phosphor powder is dispersed therein to convert the wavelength of light, thereby producing white light.

Since a light emitting diode chip is a semiconductor device, which generates heat while operating, the heat may cause discoloration of a transparent resin encapsulation unit. Such discoloration can adversely affect a light emitting device, as it is an optical device. For this reason, a sealing composition used to form a resin encapsulation unit requires high resistance to heat and discoloration.

A resin encapsulation unit of a light emitting device needs to provide appropriate durability to protect a light emitting diode chip against external forces. That is, when external forces are applied to the upper side of a product, the wires used to connect the chip and lead frames may be damaged. Therefore, there has been a need for a resin encapsulation unit having sufficient hardness.

As described above, the resin encapsulation unit may be thermally expanded due to heat generated from the light emitting diode chip. When thermal expansion occurs significantly, the wires used to connect the light emitting diode chip may be broken.

When phosphor powder is included for wavelength conversion, as in white light emitting devices, a resin encapsulation unit is required in which the phosphor powder is uniformly dispersed in order to supply homogeneous light.

### SUMMARY OF THE INVENTION

An aspect of the present invention provides a sealing composition for a light emitting device including a hybrid composite resin satisfying various properties, such as resistance to heat and discoloration as well as durability and hardness, by combining advantages of the existing polymer resin.

An aspect of the present invention provides a light emitting device including a resin encapsulation unit prepared using the sealing composition.

According to an aspect of the present invention, there is provided a sealing composition for a light emitting device, the sealing composition including: a silicone/epoxy compound resin including a silicone resin having at least one silicon atom-bonded hydroxyl group and an epoxy resin having at least one oxirane group while the hydroxyl group of the silicone resin and the oxirane group of the epoxy resin are chemically bound to each other.

The silicone resin may include any one of polysilane, polysiloxane and a combination thereof. The epoxy resin may include at least one epoxy resin selected from the group consisting of a bisphenol-F epoxy resin, a bisphenol-A epoxy resin, a phenol novolac epoxy resin and a cresol novolac epoxy resin.

The silicone/epoxy compound resin may include 80 to 95 wt % of silicone resin.

The sealing composition may further include at least one kind of phosphor powder to convert light having a predetermined wavelength into light having another wavelength. The sealing composition may further include transparent fine particles formed of transparent materials having a predetermined refractive index to scatter light being made incident, thereby providing a more homogenous white light even when the phosphor powder is not completely uniformly dispersed.

According to another aspect of the present invention, there is provided a light emitting device including: a semiconductor light emitting diode chip; first and second electrode structures electrically connected to the semiconductor light emitting diode chip; and a resin encapsulation unit provided to seal the semiconductor light emitting diode chip, wherein the resin encapsulation unit may include a sealing composition for a light emitting device including a silicone/epoxy compound resin including a silicone resin having at least one silicon atom-bonded hydroxyl group and an epoxy resin having at least one oxirane group while the hydroxyl group of the silicone resin and the oxirane group of the epoxy resin are chemically bound to each other.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a scanning electron microscopy (SEM) picture illustrating an epoxy/silicone compound resin according to an exemplary embodiment of the present invention;

FIG. 2 is a scanning electron microscopy (SEM) picture illustrating an epoxy/silicone mixed resin according to a comparative example;

FIG. 3 is a side cross-sectional view illustrating a light emitting device according to an exemplary embodiment of the present invention;

FIG. 4 is a side cross-sectional view illustrating a light emitting device according to a preferred embodiment of the present invention;and

FIG. 5 is a graph illustrating dispersion of color coordinates with respect to a light emitting device including an epoxy/silicone mixed resin containing a small amount of silicone resin.

### DETAILED DESCRIPTION OF THE PREFERRED EMBODIMENT

Exemplary embodiments of the present invention will now be described in detail with reference to the accompanying drawings.

In the present invention, a hybrid composite material having a silicone resin and an epoxy resin bound to each other is provided to improve the characteristics of a resin encapsulation unit of a light emitting device, that is, a sealing composition for the light emitting device.

A silicone resin has a relatively higher chemical resistance, thermal resistance and discoloration resistance than other sealing compositions. On the other hand, a silicone resin has low durability due to its relatively low hardness, and is likely to be separated from a ceramic, used to form a package body, due to low adhesiveness. On the other hand, an epoxy resin has high resistance against external forces because of its relatively high hardness, high durability because of high adhesiveness, and its high resistance to thermal shock because of its relatively lower thermal expansion coefficient according to temperature.

In order to combine these advantages of silicon and epoxy resins, a new compound resin is prepared by chemical synthesis instead of a mixed resin prepared by a simple mixing method. The new compound resin obtained by chemical synthesis can be used as an excellent sealing composition for a light emitting device with a complementary combination of the two kinds of resins.

As for a silicone resin for the synthesis of a new sealing composition, a silicone resin containing at least one silicon atom-bonded hydroxyl group is used. The silicone resin, which can be employed in an exemplary embodiment of the invention, includes any one of polysilane, polysiloxane and a combination thereof. However, the invention is not limited thereto.

Examples of polymeric silane containing a hydroxyl group may include triphenyl silanol, diphenyl methyl silanol, dimethyl silane diol and vinyl diphenyl silane diol.

An epoxy resin for the synthesis of the new sealing composition may include at least one epoxy resin selected from the group consisting of a bisphenol-F epoxy resin, a bisphenol-A epoxy resin, a phenol novolac epoxy resin and a cresol novolac epoxy resin.

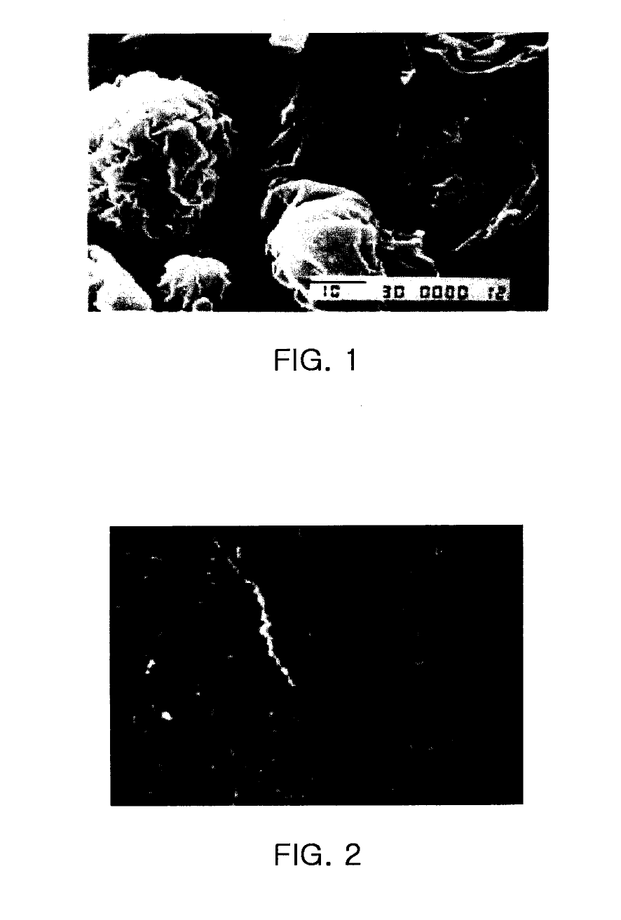

A sealing composition, which is a new silicone/epoxy compound resin may be prepared by chemically bonding a hydroxyl (OH) group of the silicone resin and an oxirane group of the epoxy resin. FIG. 1 is a scanning electron microscopy (SEM) picture illustrating a new silicone/epoxy compound resin prepared by chemically bonding a hydroxyl (OH) group of a silicone resin and an oxirane group of an epoxy resin. On the other hand, in FIG. 2, an epoxy resin and a silicone resin are simply mixed.

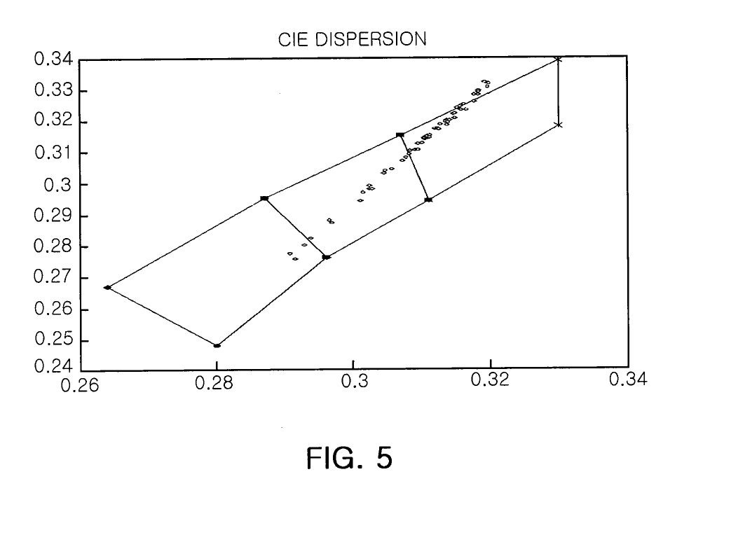

Preferably, the silicone/epoxy compound resin contains 80 to 95 wt % of silicone resin. When the silicone resin is added at a ratio of 80 wt % or less, that is, when the epoxy resin is added at a ratio of 20 wt % or more, it is difficult to ensure the uniform dispersion of phosphors. Therefore, the color coordinates (70 wt % silicone resin), shown the in FIG. 5, show too spatial a dispersion.

When transparent fine particles are added to scatter light, if the content of the silicone resin exceeds 80 wt %, it is possible to appropriately disperse the transparent fine particles within the resin encapsulation unit. On the other hand, less than 80 wt % of the silicone resin increases the hardness of the mixed resin, used to form the resin encapsulation unit, and thus the transparent fine particles may not be appropriately dispersed and precipitate.

A sealing composition according to an exemplary embodiment of the invention may be effectively used to form a resin encapsulation unit to form a wavelength conversion unit. Phosphor powder, which can be employed in the exemplary embodiment of the invention, includes at least one phosphor selected from the group consisting of garnet doped with rare earths, alkaline earth metal sulfides doped with rare earths, thiogallates doped with rare earths, aluminates doped with rare earths, and orthosilicates doped with rare earths.

According to an exemplary embodiment of the invention, even though phosphor powder can be uniformly dispersed in comparison to the use of epoxy resin alone, the phosphor powder may not be uniformly dispersed due to the inclusion of the epoxy resin in comparison to the use of the silicone resin alone. This problem can be effectively solved by adding transparent fine particles to scatter light.

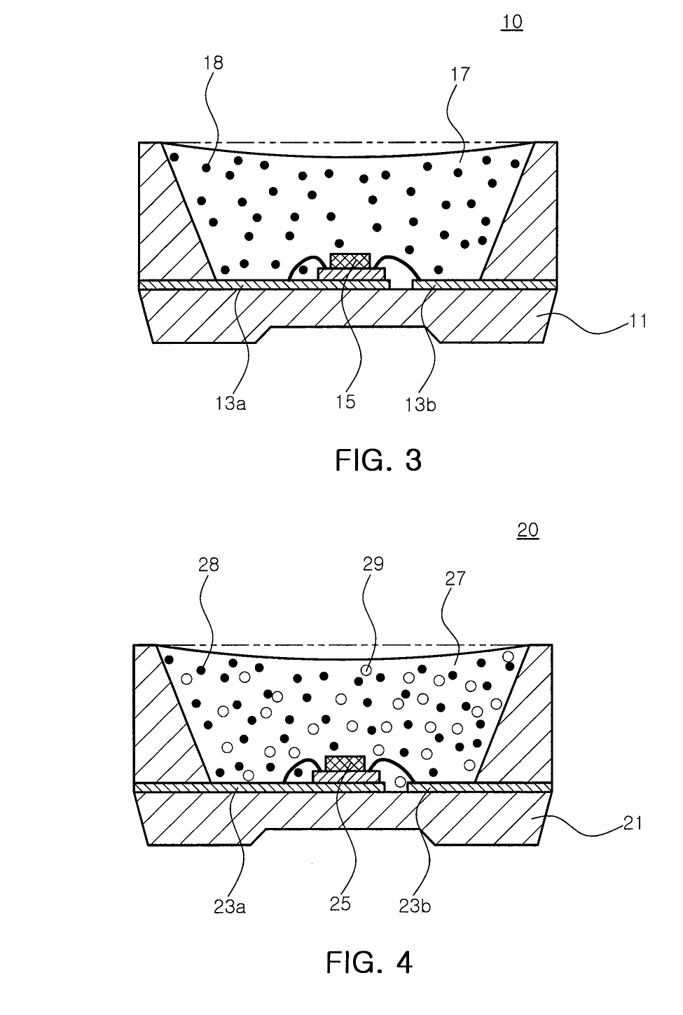

FIG. 3 is a side cross-sectional view illustrating a light emitting device according to an exemplary embodiment of the invention.

Referring to FIG. 3, a light emitting device 10 includes a package substrate 11 that has a light emitting diode chip 15 mounted therein.

The package substrate 11 may include a recess to mount a light emitting diode chip 15 therein and first and second electrode structures 13a and 13b exposed to the bottom of the recess. The first and second electrode structures 13a and 13b may include general lead frames. When a package substrate, such as a ceramic substrate, is used, the first and second electrode structures 13a and 13b may include electrode pads formed on the top and bottom surfaces thereof and via holes connecting them.

Both electrodes (not shown) of the light emitting diode chip 15 may be connected to the first and second electrode structures 13a and 13b using wires. A resin encapsulation unit 17 is formed within the recess of the package substrate 11 to encompass the light emitting diode chip 15.

The resin encapsulation unit 17, which is employed in this embodiment, includes a silicone/epoxy compound resin comprising a silicone resin containing at least one silicon atom-bonded hydroxyl group and an epoxy resin containing at least one oxirane group. Here, the hydroxyl group of the silicone resin and the oxirane group of the epoxy resin are chemically bound to each other.

The silicone resin may include any one of polysilane, polysiloxane and a combination thereof. The epoxy resin may include at least one epoxy resin selected from the group consisting of a bisphenol-F epoxy resin, a bisphenol-A epoxy resin, a phenol novolac epoxy resin and a cresol novolac epoxy resin. Preferably, the silicone/epoxy compound resin comprises 80 to 95 wt % of silicone resin.

The resin encapsulation unit 17 may include phosphor powder 18 that is dispersed therein and is used to convert the wavelength of light emitted from the light emitting diode chip 15 to another wavelength. Phosphor powder, which can be employed in this embodiment, includes at least one phosphor selected from the group consisting of garnet doped with rare earths, alkaline earth metal sulfides doped with rare earths, thiogallates doped with rare earths, aluminates doped with rare earths, and orthosilicates doped with rare earths.

For example, the light emitting diode chip 15 may be a blue light emitting diode, and the phosphor powder may include a combination of red and green phosphors or a combination of red, yellow and green phosphors to emit white light.

FIG. 4 is a side cross-sectional view illustrating a light emitting device according to a preferred embodiment of the invention.

As shown in FIG. 4, alight emitting device 20 according to this embodiment includes a light emitting diode chip 25 and a package substrate 21 having the light emitting diode chip 25 mounted therein.

In a similar manner to the above-embodiment, the package substrate 21 according to this embodiment may have a recess to mount the light emitting diode chip 25 therein. Further, the light emitting device 20 may include first and second electrode structures 23a and 23b that are exposed to the bottom of the recess.

Both electrodes (not shown) of the light emitting diode chip 25 may be electrically connected to the first and second electrode structures 23a and 23b using wires. This electrical connection may be realized by flip-chip bonding according to a type of a semiconductor chip.

A resin encapsulation unit 27 is formed within the recess of the package substrate 21 to encompass the light emitting diode chip 25.

The resin encapsulation unit 27, which is employed in this embodiment, includes a silicone/epoxy compound resin that has a silicone resin containing at least one silicon atom-bonded hydroxyl group and an epoxy resin containing at least one oxirane group. Here, the hydroxyl group of the silicone resin and the oxirane group of the epoxy resin are chemically bound to each other.

The resin encapsulation unit 27 may include phosphor powder 28 that is dispersed therein and is used to convert the wavelength of light emitted from the light emitting diode chip 25 into another wavelength. For example, the light emitting diode chip 25 may be a blue light emitting diode, and the phosphor powder 28 may include a combination of red and green phosphors and a combination of red, yellow and green phosphors to emit white light.

Further, in this embodiment, the resin encapsulation unit 27 may further include transparent fine particles 29 that are dispersed therein to scatter light and are formed of transparent materials having a predetermined refractive index.

In this embodiment, the transparent fine particles 29 may have a higher refractive index than the adjacent resin encapsulation unit 27 in order to scatter light more effectively. Therefore, when the phosphor powder may not be uniformly dispersed due to the inclusion of the epoxy resin in comparison to the use of the silicone resin alone, the transparent fine particles 29, which are included to scatter light, enable the light emitting device to supply homogeneous light.

As set forth above, according to exemplary embodiments of the invention, as a sealing composition for a light emitting device is provided by producing a new composite material having a hydroxyl (OH) group of silicone and an oxirane group of epoxy bound to each other, a resin encapsulation unit having excellent light transmittance and mechanical stability can be provided in which advantages of a silicone resin, such as excellent heat resistance, chemical resistance and discoloration resistance and an epoxy resin, such as high hardness and a low thermal expansion coefficient, are combined.

Further, when a resin encapsulation unit is provided as a wavelength conversion unit containing phosphor powder, uniform dispersion of the phosphor powder can be achieved in comparison with the use of the epoxy resin alone. Further, even when the phosphor powder may not be uniformly dispersed due to the inclusion of the epoxy resin, homogenous light can be supplied by adding transparent fine particles to scatter light.

While the present invention has been shown and described in connection with the exemplary embodiments, it will be apparent to those skilled in the art that modifications and variations can be made without departing from the spirit and scope of the invention as defined by the appended claims.

What is claimed is:

1. A sealing composition for a light emitting device, the sealing composition comprising:
a silicone/epoxy compound resin including a silicone resin having at least one silicon atom-bonded hydroxyl group and an epoxy resin having at least one oxirane group while the hydroxyl group of the silicone resin and the oxirane group of the epoxy resin are chemically bound to each other.

2. The sealing composition of claim 1, wherein the silicone resin comprises any one of polysilane, polysiloxane and a combination thereof.

3. The sealing composition of claim 1, wherein the epoxy resin comprises at least one epoxy resin selected from the group consisting of a bisphenol-F epoxy resin, a bisphenol-A epoxy resin, a phenol novolac epoxy resin and a cresol novolac epoxy resin.

4. The sealing composition of claim 1, wherein the silicone/epoxy compound resin comprises 80 to 95 wt % of silicone resin.

5. The sealing composition of claim 1, further comprising at least one kind of phosphor powder to convert light having a predetermined wavelength into light having another wavelength.

6. The sealing composition of claim 5, further comprising transparent fine particles formed of transparent materials having a predetermined refractive index to scatter light being made incident.

7. A light emitting device comprising:
a semiconductor light emitting diode chip;
first and second electrode structures electrically connected to the semiconductor light emitting diode chip; and
a resin encapsulation unit provided to seal the semiconductor light emitting diode chip,
wherein the resin encapsulation unit comprises a sealing composition for a light emitting device including a silicone/epoxy compound resin including a silicone resin having at least one silicon atom-bonded hydroxyl group and an epoxy resin having at least one oxirane group while the hydroxyl group of the silicone resin and the oxirane group of the epoxy resin are chemically bound to each other.

8. The light emitting device of claim 7, wherein the silicone resin comprises any one of polysilane, polysiloxane and a combination thereof.

9. The light emitting device of claim 7, wherein the epoxy resin comprises at least one epoxy resin selected from the group consisting of a bisphenol-F epoxy resin, a bisphenol-A epoxy resin, a phenol novolac epoxy resin and a cresol novolac epoxy resin.

10. The light emitting device of claim 7, wherein the silicone/epoxy compound resin comprises 80 to 95 wt % of silicone resin.

11. The light emitting device of claim 7, wherein the resin encapsulation unit further comprises at least one kind of phosphor powder dispersed therein and converting the wavelength of light emitted from the semiconductor light emitting diode chip into another wavelength.

12. The light emitting device of claim 11, wherein the resin encapsulation unit further comprises transparent fine particles dispersed therein and formed of transparent materials having a predetermined refractive index to scatter light.
